(19) United States
(12) Patent Application Publication
(10) Pub. No.: US 2025/0253145 A1
(43) Pub. Date: Aug. 7, 2025

(54) SUBSTRATE PROCESSING METHOD

(71) Applicant: ASM IP Holding B.V., Almere (NL)

(72) Inventors: Kai Matsuhisa, Tokyo (JP); Trigagema Gama, Yamato-shi (JP); Satomi Ota, Tokyo (JP)

(21) Appl. No.: 19/043,792

(22) Filed: Feb. 3, 2025

Related U.S. Application Data
(60) Provisional application No. 63/550,140, filed on Feb. 6, 2024.

(51) Int. Cl. H01L 21/02; C23C 16/04; C23C 16/40; C23C 16/455; C23C 16/56; H01J 37/32

(52) U.S. Cl. CPC H01L 21/02304; C23C 16/045; C23C 16/401; C23C 16/45538; C23C 16/45553; C23C 16/56; H01J 37/32449; H01L 21/02164; H01L 21/02211; H01L 21/0228; H01L 21/0234; H01J 2237/332

(57) ABSTRACT

Provided is a method of filling a gap without seam or void within a gap. According to an embodiment of the present disclosure, the gap fill method comprises forming a first inhibiting layer on the upper portion of the gap, forming a second inhibiting layer on the upper portion of the gap by removing the first inhibiting layer, forming a silicon-containing layer and performing a post treatment to remove residual impurities from the silicon-containing layer, wherein the post treatment comprises a first treatment and a second treatment.

### CROSS-REFERENCE TO RELATED APPLICATIONS

This application claims priority to U.S. Provisional Patent Application Ser. No. 63/550,140 filed Feb. 6, 2024 titled SUBSTRATE PROCESSING METHOD, the disclosure of which is hereby incorporated by reference in its entirety.

### FIELD OF INVENTION

The disclosure relates to a substrate processing method, more particularly, to a method of filling a gap without forming a seam or a void.

### BACKGROUND OF THE DISCLOSURE

A semiconductor device comprises a great number of transistors. The transistors are required to be insulated from surroundings not to be interrupted electrically from neighboring transistors. To that end, an insulating structure is introduced between transistors. STI (Shallow Trench Isolation) is a gap structure formed between transistors and is filled with an insulation layer such as SiO₂. The insulation layer filling the STI is required to have no voids or seams and to have a high etch resistance for a low electric leakage.

A flowable CVD method is widely used to fill the gap with the insulation layer. The flowable CVD method is employed to fill the gap from the bottom, followed by an annealing process at high temperature. The annealing process, however, causes damage to the underlayer of the gap (i.e., a crack), resulting in degradation of electrical characteristics.

To solve the problem mentioned above, a plasma atomic layer deposition (PEALD) method is employed to fill the gap at low temperature. In order to improve a gap fill efficiency, an inhibitor is introduced to the gap-fill method such that a formation of SiO₂ layer is inhibited in an upper portion of the gap. In contrast, the formation of SiO₂ layer is promoted in a lower portion of the gap, enabling to fill the gap from the bottom.

As an inhibitor, a nitrogen activated by a power source (e.g., a plasma generator or a RF generator) is usually used. The activated nitrogen adsorbs on the upper portion of the gap to form an inhibiting layer thereon, followed by forming the SiO₂ layer on the gap. In forming the SiO₂ layer on the gap, the silicon source layer is not formed on the upper portion of the gap due to the inhibiting layer. In contrast, the silicon source reacts with bonding sites (i.e., —OH sites) on the lower portion of the gap. The gap fill cycle using the inhibitor in PEALD method is repeated cyclically to fill the gap with a SiO₂ layer.

However, as the number of cycles to fill the gap with the SiO₂ layer increases, the silicon source reacts with the inhibiting layer (i.e., a nitrogen layer) on the upper portion of the gap and a SiN layer is formed thereon while the SiO₂ layer is formed on the lower portion of the gap, leading to a void within the gap in the end. The void results from a difference in activation energy to form a film under the plasma.

It is known that under the plasma, the activation energy to form the SiO₂ layer is 17.4 kJ/mol and the activation energy to form the SiN layer is 6.7 kJ/mol. In other words, the SiN layer is more easily formed.

FIGS. 1A to 1E illustrate an existing SiO₂ gap-fill method using a nitrogen inhibitor (i.e., N₂ plasma) in which a SiN layer is formed on a nitrogen inhibiting layer on an upper portion of a gap, while a lower portion of the gap is filled with a SiO₂ layer.

In FIG. 1A, a gap 2 may be formed in a substrate 1. In FIG. 1B, a nitrogen inhibiting layer 3 may be formed on the upper portion of the gap 2 by supplying a nitrogen-containing gas (i.e., N₂) as an inhibitor to the substrate 1. The location of the inhibiting layer 3 may be controlled to be formed on the upper portion of the gap 2 by adjusting process conditions such as plasma power, plasma frequency, nitrogen flow rate and nitrogen supply time etc.

In FIG. 1C, the gap 2 may be filled with the SiO₂ layer 4 by supplying a silicon source gas and an oxygen-containing gas. The SiO₂ layer 4 may be formed by PEALD method in which an oxygen plasma may be supplied, for instance. Due to the inhibiting layer 3 formed on the upper portion of the gap, the SiO₂ layer 4 may be formed on the lower portion of the gap 2, filling the gap 2 from the bottom. FIG. 1C may be repeated a plurality of times.

In FIG. 1D, as FIG. 1C continues to be repeated, a SiN layer 5 may be formed on the upper portion of the gap 2, while the lower portion of the gap 2 is filled with the SiO₂ layer 4 from the bottom. As aforementioned, the activation energy of forming a SiN layer is 6.7 kJ/mol, lower than 17.4 kJ/mol, the activation energy for forming a SiO₂ layer. Thus, the SiN layer 5 may be formed on the upper portion of the gap 2 while FIG. 1C repeats.

In FIG. 1E, a void 6 may be formed in the gap 2 as the FIG. 1C and FIG. 1D are repeated. The void 6 formed in the gap 2 may deteriorate the insulation property of the semiconductor device and degrade the electrical characteristics of the device.

Therefore, it is required to suppress formation of the SiN layer on the upper portion of the gap, while promoting formation of the SiO₂ layer on the lower portion of the gap in the SiO₂ gap fill method using the inhibitor.

### SUMMARY OF THE DISCLOSURE

The disclosure discloses a method of filling a gap, more particularly, a method of filling a gap with a SiO₂ layer by using an inhibitor, while suppressing formation of a SiN layer on the upper portion of the gap.

In one or more embodiments, the method of filling the gap of the substrate may comprise providing the substrate with the gap in a reactor, forming a first inhibiting layer on the substrate by supplying a first inhibitor comprising a nitrogen-containing gas while applying a first power to the reactor, forming a second inhibiting layer by supplying a second inhibitor comprising a fluorine-containing gas while applying a second power to the reactor and removing the first inhibiting layer, and forming a silicon-containing layer on the substrate, wherein the first inhibiting layer and the second inhibiting layer may be formed on an upper portion of the gap and the silicon-containing layer may be formed on a lower portion of the gap.

In one or more embodiments, the silicon-containing layer may be a silicon oxide formed by repeating a method comprising: supplying a silicon source gas, followed by supplying an oxygen-containing gas while applying a third power.

In one or more embodiments, the silicon source gas may comprise at least one of trisilylamine ((SiH₃)₃N); disilane ((SiH₃)₂); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane(SiH₃N(iPr)₂); tetraethylorthosilicate (Si(OEt)₄); 1,2-bis(triethoxysilyl)ethane ([CH₂Si(OC₂H₅)₃]₂); Bis(triethoxysilyl)methane (CH₂[Si(OC₂H₅)₃]₂); bis(methyldiethoxysilyl)ethane ([CH₂Si(OC₂H₅)₂(OCH₃)]₂); bis(methyldiethoxysilyl)methane (CH₂[Si(OC₂H₅)₂(OCH₃)]₂); Aminopropyltrimethoxysilane (NH₂C₃H₆)Si(OCH₃)₃; silicon tetrachloride (SiCl₄); hexachlorodisilane (Si₂Cl₆); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄); trisilane (Si₃H₈) or a mixture thereof.

In one or more embodiments, the oxygen-containing gas may comprise at least one of O₂, O₃, or H₂O or a mixture thereof.

In one or more embodiments, the first inhibitor may comprise at least one of N₂, NH₃, NH₄, N₂H₂, or N₂H₄ or a mixture thereof.

In one or more embodiments, the second inhibitor may comprise at least one of F₂, SF₆, CF₄, C₂F₆, CHF₃, CH₂F₂, ClF₃, NF₃, C₃F₈, C₄F₈, HF, or SiF₄ or a mixture thereof.

In one or more embodiments, the first power may be applied with a power of between about 50 W and about 2,000 W at a frequency of between about 10 MHz and about 30 MHz.

In one or more embodiments, the first power may be applied with an additional power of between about 50 W and about 500 W at a frequency of between about 300 kHz and about 1 MHz.

In one or more embodiments, the second power may be applied with a power of between about 50 W and about 100 W at a frequency of between about 300 kHz and about 20 MHz.

In one or more embodiments, the second power may be applied with an additional power of between about 15 W and about 500 W at a frequency of between about 300 kHz and about 1 MHz.

In one or more embodiments, the third power may be between about 100 W and about 300 W at a frequency of between about 10 MHz and about 30 MHz.

In one or more embodiments, the method of filling the gap of the substrate may further comprise performing a post treatment to the silicon-containing layer.

In one or more embodiments, the post treatment may comprise a first treatment by supplying a first treatment gas comprising at least one of a nitrogen-containing gas and a hydrogen-containing gas to remove the fluorine from the silicon-containing layer while applying a fourth power, and a second treatment by supplying a second treatment gas comprising at least one of an oxygen-containing gas and a hydrogen-containing gas to remove the nitrogen from the silicon-containing layer while applying a fifth power.

In one or more embodiments, the first treatment gas may comprise at least one of N₂, NH₃, NH₄, N₂H₂, N₂H₄, or H₂ or a mixture thereof, and the second treatment gas may comprise at least one of O₂, O₃, H₂O, H₂O₂, or H₂ or a mixture thereof.

In one or more embodiments, each of the fourth power and the fifth power may be applied with a power of between about 50 W and about 2,000 W at a frequency of between about 10 MHz and about 30 MHz.

In one or more embodiments, each of the fourth power and the fifth power may be applied with an additional power of between about 15 W and about 500 W at a frequency of between 300 kHz and about 1 MHz.

In one or more embodiments, each of forming the first inhibiting layer, forming the second inhibiting layer, forming the silicon-containing layer, performing the first treatment and performing the second treatment may be repeated at least one time.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A to 1E illustrate the existing SiO₂ gap-fill method using a nitrogen inhibitor in which a SiN layer is formed on the upper portion of the gap.

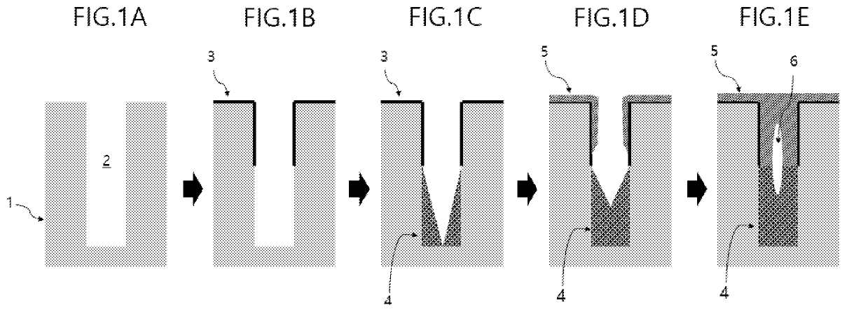

FIG. 2 illustrates the gap-fill method according to an embodiment of the present disclosure.

FIGS. 3A to 3F illustrate the gap-fill method schematically according to an embodiment of FIG. 2.

FIGS. 4A to 4D illustrate the species formed on the surface of the gap according to FIG. 2 and FIGS. 3A to 3F.

FIG. 5 illustrates a gap fill method according to another embodiment of the present disclosure.

FIG. 6 illustrates the details of the post treatment according to another embodiment of the present disclosure.

FIG. 7A is a TEM photo showing the gap filled with the SiO₂ layer and FIG. 7B is an EDX (Energy Dispersive X-ray Spectroscopy) analysis results showing the amount of fluorine in the corresponding SiO₂ layer when the first treatment and the second treatment are not performed.

FIG. 8A is a TEM photo showing the gap filled with the SiO₂ layer and FIG. 8B is an EDX (Energy Dispersive X-ray Spectroscopy) analysis results showing the amount of fluorine in the corresponding SiO₂ layer when the first treatment and the second treatment are performed.

FIG. 9A illustrates a timing graph for the gap fill method according to an embodiment of the present disclosure.

FIG. 9B illustrates a timing graph for the gap fill method according to an embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

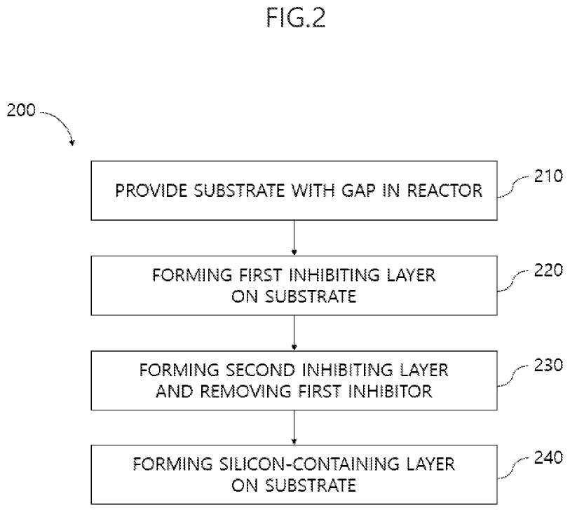

FIG. 2 illustrates a gap fill method according to an embodiment of the present disclosure.

In STEP 210 of the gap fill method 200 in FIG. 2, a substrate with a gap may be provided in a reactor. The gap in the substrate may be a structure to isolate transistors from surroundings (e.g., STI (shallow trench isolation)), for instance, or any other-shaped trench in DRAM or 3D VNAND devices.

In STEP 220, a first inhibiting layer may be formed on the substrate. The first inhibiting layer may be formed by supplying a first inhibitor to the substrate. The first inhibitor may be activated by a first power applied to the reactor in-situ or remotely. The surface of the substrate may comprise bonding sites (e.g., —OH). The inhibitor may react with the bonding sites located on the upper portion of the gap and form the first inhibiting layer comprising inhibiting sites thereon (e.g., —HN).

In order for the first inhibiting layer to be formed on the upper portion of the gap, some process parameters (e.g., pressure, supply time of the first inhibitor, flow rate or the first inhibitor and plasma conditions etc.) may be adjusted. For instance, the first inhibitor may be supplied during a short period of time while applying a low intensity of high frequency RF power.

In some embodiments, the first power may be applied with a power of between about 50 W and about 2,000 W at a frequency of between about 10 MHz and about 30 MHz. More specifically, the first power of between about 300 W and about 1,500 W at a frequency of between about 10 MHz and about 20 MHz may be applied. The first power may be applied for about 6 seconds to about 50 seconds.

In additional embodiments, the first power may be applied with an additional power of between about 50 W and about 500 W at a frequency of between about 300 kHz and about 1 MHz. That is, a dual frequency first power comprising a high frequency power and a low frequency power may be applied to the reactor.

The first inhibitor may comprise a nitrogen-containing gas. In one embodiment of the present disclosure, the first inhibitor may comprise at least one of N₂, NH₃, NH₄, N₂H₂, or N₂H₄ or a mixture thereof.

In STEP 230, a second inhibiting layer may be formed on the upper portion of the gap and remove the first inhibiting layer formed thereon at STEP 210. The second inhibiting layer may be formed by supplying a second inhibitor to the substrate. The second inhibitor may be activated by a second power applied to the reactor in-situ or remotely.

In some embodiments, the second power may be applied with a power of between about 15 W and about 500 W at a frequency of between about 10 MHz and about 30 MHz. More specifically, the first power of between about 50 W and about 100 W at a frequency of between about 10 MHz and about 20 MHz may be applied. The second power may be applied for about 0.1 seconds to about 5 seconds to form the second inhibiting layer.

In additional embodiments, the second power may be applied with an additional power of between about 15 W and about 500 W at a frequency of between about 300 kHz and about 1 MHz. That is, a dual frequency second power comprising a high frequency power and a low frequency power may be applied to the reactor.

The second inhibitor may comprise a fluorine-containing gas. In one embodiment of the present disclosure, the second inhibitor may comprise at least one of F₂, SF₆, CF₄, C₂F₆, CHF₃, CH₂F₂, ClF₃, NF₃, C₃F₈, C₄F₈, HF, or SiF₄ or a mixture thereof. The second inhibitor may remove the first inhibiting layer formed on the upper portion of the gap and form the second inhibiting layer thereon on which the first inhibiting layer was previously formed.

The surface of the gap may comprise bonding sites (i.e., —OH) formed on the lower portion of the gap and the first inhibiting layer (i.e., —HN) formed on the upper portion of the gap. In STEP 230, the second inhibitor (i.e., a fluorine-containing gas) is thought to react with the first inhibiting layer (i.e., —HN) formed on the upper portion of the gap better than the bonding sites formed on the lower portion of the gap, resulting in removing the first inhibiting layer. As a result, the second inhibiting layer (i.e., —F) may be formed on the upper portion of the gap on which the first inhibiting layer was previously formed better than on the lower portion of the gap.

That is, the difference of reactivity between the second inhibitor and the different surface layers may enable the second inhibiting layer to be formed selectively on the upper portion of the gap other than on the lower portion of the gap. Therefore, the bottom-up gap fill may continue such that the upper portion of the gap may keep wide-open, and the SiN layer may be suppressed from being formed on the upper portion of the gap during filling the gap (e.g., during repeating STEP 240).

In STEP 240, a silicon-containing layer may be formed to fill the gap. The silicon-containing layer may be an insulation layer. For instance, the silicon-containing layer may be SiO₂ formed by PEALD method in which a silicon source gas and an activated oxygen-containing gas as a reactant may be supplied alternately and sequentially. The STEP 240 may be repeated a plurality of times until the gap is filled.

The silicon source gas may comprise at least one of trisilylamine ((SiH₃)₃N); disilane ((SiH₃)₂); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane(SiH₃N(iPr)₂); tetraethylorthosilicate (Si(OEt)₄); 1,2-bis(triethoxysilyl)ethane ([CH₂Si(OC₂H₅)₃]₂); Bis(triethoxysilyl)methane (CH₂[Si(OC₂H₅)₃]₂); bis(methyldiethoxysilyl)ethane ([CH₂Si(OC₂H₅)₂(OCH₃)]₂); bis(methyldiethoxysilyl)methane (CH₂[Si(OC₂H₀)₂(OCH₃)]₂); Aminopropyltrimethoxysilane (NH₂C₃H₆)Si(OCH₃)₃; silicon tetrachloride (SiCl₄); hexachlorodisilane (Si₂Cl₆); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄); or trisilane (Si₃H₈) or a mixture thereof.

The reactant may comprise an oxygen-containing gas to form the SiO₂ layer. For instance, at least one of O₂, O₃, or H₂O or a mixture thereof may be supplied to form the SiO₂ layer. The oxygen-containing gas may be activated by applying a third power to the reactor.

In some embodiment, the third power may be applied with a power of between about 100 W and about 300 W at a frequency of between about 10 MHz and about 30 MHz. More specifically, the third power may be between about 150 W and about 250 W at a frequency between about 10 MHz and about 20 MHz to form the silicon-containing layer. The third power may be applied for about 0.1 seconds to about 0.5 seconds.

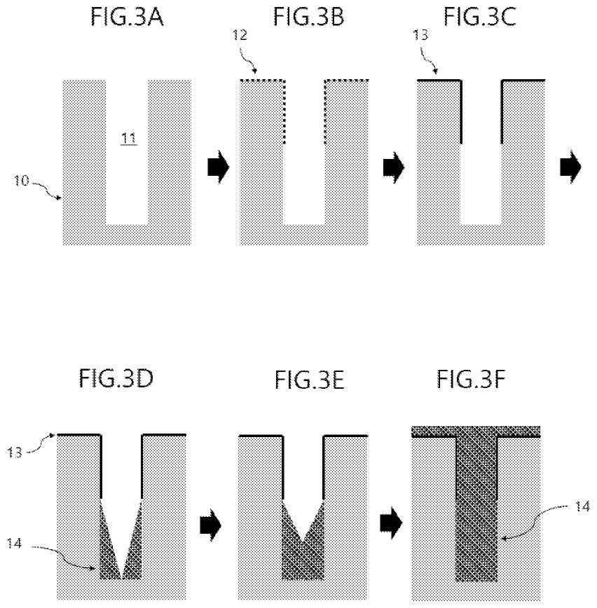

FIGS. 3A to 3F illustrate a gap-fill method schematically according to an embodiment of FIG. 2.

In FIG. 3A, a gap 11 may be formed in a substrate 10. In FIG. 3B, a first inhibiting layer 12 may be formed on the upper portion of the gap 11 by supplying a first inhibitor to the substrate 10. The first inhibitor may be activated by a power applied to the reactor in-situ or remotely. The location of the first inhibiting layer 12 may be controlled to be formed on the upper portion of the gap 11 by adjusting process conditions such as plasma power, plasma frequency, flow rate of the first inhibitor and supply time of the first inhibitor etc. The first inhibitor may comprise a nitrogen-containing gas.

In FIG. 3C, the first inhibiting layer 12 may be removed from the upper portion of the gap and a second inhibiting layer 13 may be formed thereon by supplying a second inhibitor. The second inhibiting layer 13 may be formed by supplying the second inhibitor to the substrate. The second inhibitor may be activated by a power applied to the reactor in-situ or remotely. The second inhibitor may comprise a fluorine-containing gas.

In FIG. 3D, a silicon-containing layer 14 may be formed to fill the gap. The silicon-containing layer may be a SiO₂ layer. The SiO₂ layer may be formed by PEALD method by supplying a silicon source gas and an activated oxygen-containing gas alternately and sequentially. The SiO₂ layer may fill the gap 11 from the bottom, while the SiO₂ layer or the SiN layer may not be formed on the upper portion of the gap due to the second inhibiting layer 13 formed thereon as shown in FIG. 3E.

In FIG. 3F, the gap may be fully filled with the SiO₂ layer without forming a void by repeating FIG. 3D and FIG. 3E.

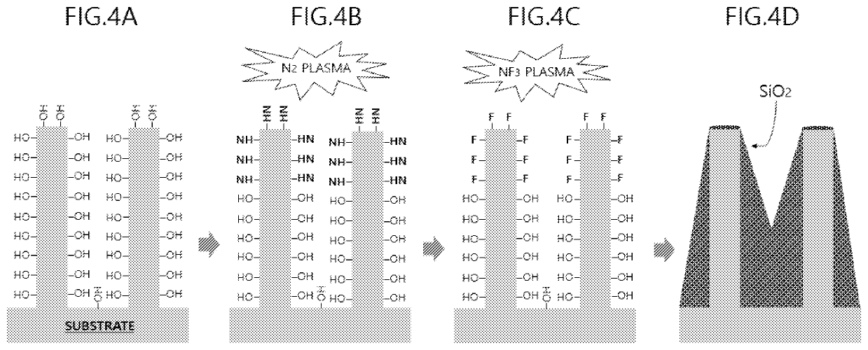

FIGS. 4A to 4D illustrate the species formed on the surface of the gap schematically according to FIG. 2 and FIGS. 3A to 3F.

In FIG. 4A, a substrate with a gap is provided. The surface of the gap may be formed with bonding sites (e.g., —OH) from the upper portion to the lower portion.

In FIG. 4B, a first inhibitor may be supplied to the gap. The first inhibitor may be a nitrogen-containing gas, N₂, for instance, activated by a power. The first inhibitor may react with the bonding sites on the upper portion of the gap, forming an inhibiting layer (e.g., NH—) thereon. FIG. 4B may correspond to STEP 220 of FIG. 2 and FIG. 3B.

In FIG. 4C, a second inhibitor may be supplied to the gap. The second inhibitor may be a fluorine-containing gas, NF₃, for instance. The second inhibitor may remove the first inhibitor formed on the upper portion of the gap and be adsorbed thereon which the first inhibiting layer was previously formed. That is, the second inhibiting layer (e.g. —F) may be formed on the upper portion of the gap, while the lower portion of the gap may still be formed with the bonding sites (i.e., —OH). FIG. 4C may correspond to STEP 230 of FIG. 2 and FIG. 3C. The chemical reaction equation between NF₃, the second inhibitor, and —HN, the first inhibiting layer, may be as follows.

NF₃+4NH→3F+NH₄(g)+2N₂(g)

In the equation above, F may form the second inhibiting layer, while NH₄ and N₂ may be removed as gaseous byproducts. In other words, the first inhibiting layer may be removed by reacting with the second inhibitor, and subsequently the second inhibiting layer may be formed on the upper portion of the gap where the first inhibiting layer was previously formed.

In FIG. 4D, the gap may be filled with a SiO₂ layer. The SiO₂ layer may be formed by PEALD method. As the cycle for forming the SiO₂ layer repeats, the gap may be filled from the bottom to the top, with no void formed therein. FIG. 4D may correspond to STEP 240 of FIG. 2, and FIGS. 3D to 3F. The second inhibiting layer (i.e., —F) may have stronger inhibiting characteristics than the first inhibiting layer (i.e., —HN). Thus, a layer formation may be suppressed on the upper portion of the gap during gap is filled with the SiO₂ layer.

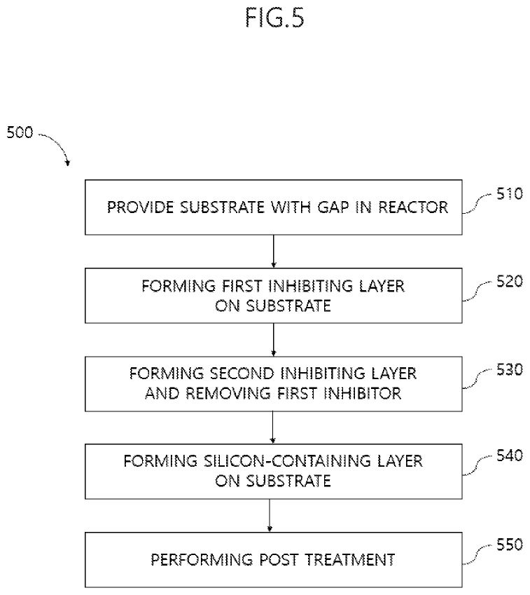

FIG. 5 illustrates a gap-fill method according to another embodiment of the present disclosure.

In FIG. 5, the gap-fill method 500 may comprise STEP 510 to STEP 550. Of them, STEP 510 to STEP 540 may be the same as STEP 210 to STEP 240 of FIG. 2.

In more detail, in STEP 510, a substrate with a gap may be provided to the reactor. In STEP 520, a first inhibiting layer may be formed on the upper portion of the gap by supplying a first inhibitor, N₂ or NH₃, for instance. In STEP 530, a second inhibiting layer may be formed on the upper portion of the gap by supplying a second inhibitor, NF₃, and removing the first inhibiting layer. In STEP 540, a SiO₂ layer is formed by PEALD method to fill the gap.

In addition to FIG. 2, in STEP 550, a post treatment may be performed. The post treatment may be performed to remove impurities from the SiO₂ layer. For instance, a nitrogen-containing gas, a residual first inhibitor, and a fluorine-containing gas, a residual second inhibitor may be removed from the SiO₂ layer.

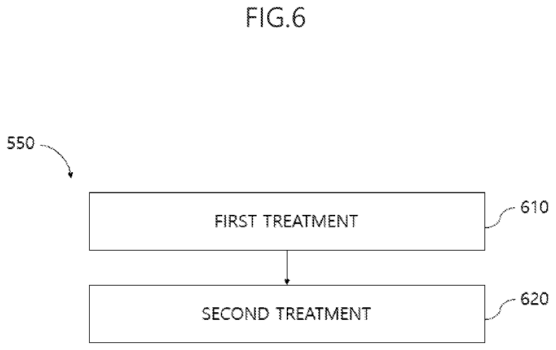

FIG. 6 illustrates the details of the post treatment according to another embodiment of the present disclosure.

In FIG. 6, the post treatment may comprise a first treatment 610 and a second treatment 620. The first treatment 610 may be performed to remove the residual fluorine-containing gas from the SiO₂ layer by supplying a first treatment gas while applying a fourth power. The first treatment gas may comprise at least one of a nitrogen-containing gas and a hydrogen-containing gas. In more detail, the first treatment gas may comprise at least one of N₂, NH₃, NH₄, N₂H₂, N₂H₄, or H₂ or a mixture thereof. The first treatment gas may react with the residual fluorine-containing gas to form a fluorine compound. The fluorine compound (e.g., NF₃, HF etc.) may be removed as gaseous byproducts.

The second treatment 620 may be performed to remove the residual nitrogen-containing gas from the SiO₂ layer by supplying a second treatment gas while applying a fifth power. The second treatment gas may comprise comprising at least one of an oxygen-containing gas and a hydrogen-containing gas. In more detail, the second treatment gas may comprise at least one of O₂, O₃, H₂O₂, H₂O, or H₂ or a mixture thereof. The second treatment gas may react with the residual nitrogen-containing gas to form a nitrogen compound. The nitrogen compound (e.g., NO₂, N₂O, NH₃ etc.) may be removed as gaseous byproducts.

In another embodiment of the present disclosure, the first treatment 610 may be performed to remove the residual nitrogen-containing gas from the SiO₂ layer by supplying an oxygen-containing gas as a first treatment gas, followed by the second treatment 620 to remove the residual fluorine-containing gas from the SiO₂ layer by supplying the nitrogen-containing gas as a second treatment gas.

In some embodiments, each of the fourth power and the fifth power may be applied with a power of between about 50 W and about 2,000 W at a frequency of between about 10 MHz and about 30 MHz. More specifically, each of the fourth power and the fifth power may be between about 200 W and about 600 W at a frequency of between about 10 MHz and about 20 MHz to perform the post treatment.

The first treatment 610 may be performed for about 10 seconds to about 150 seconds and the second treatment 620 may be performed for about 0.5 seconds to about 2 seconds.

In additional embodiments, each of the fourth power and the fifth power may be applied with an additional power of between about 15 W and about 500 W at a frequency of between about 300 kHz and about 1 MHz. That is, each of a dual frequency fourth power and a dual frequency fifth power comprising a high frequency power and a low frequency power may be applied to the reactor.

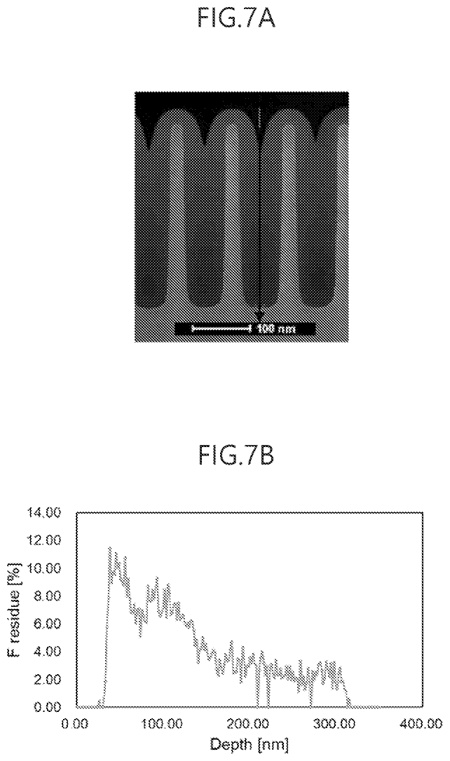

FIG. 7A is a TEM (Transmission Electron Microscope) photo image showing a gap filled with a SiO₂ layer. FIG. 7B is an EDX (Energy Dispersive X-ray Spectroscopy) analysis results showing an amount of fluorine in the corresponding SiO₂ layer by depth (the direction of the arrow in FIG. 7A) when the first treatment and the second treatment are not performed. FIG. 7A and FIG. 7B may be a result of performing FIG. 2.

As shown in FIG. 7A, the gap is filled with SiO₂ layer without forming a void therein. In FIG. 7B, the fluorine in the SiO₂ film is between more than 2% and 12% and unevenly distributed by depth. FIG. 7B shows that the fluorine is distributed more on an upper portion of the gap (low depth region). In other words, FIG. 7A and FIG. 7B show that the second inhibiting layer is formed on the upper portion of the gap according to an embodiment of FIG. 2.

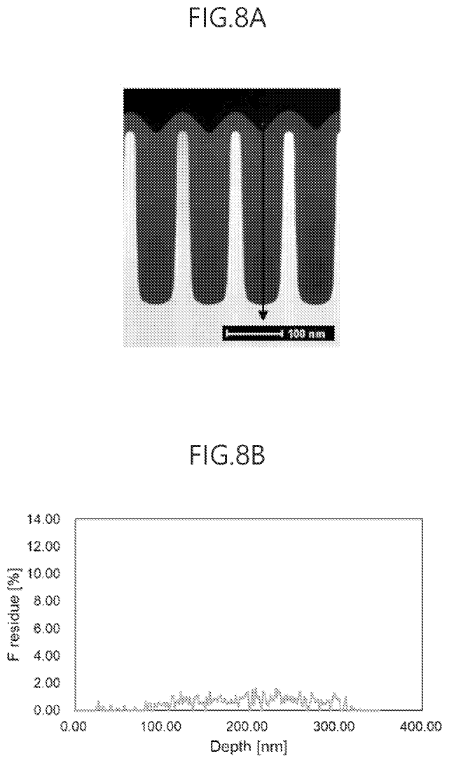

FIG. 8A is a TEM (Transmission Electron Microscope) photo image showing the gap filled with SiO₂ layer. FIG. 8B is an EDX (Energy Dispersive X-ray Spectroscopy) analysis results showing the amount of fluorine in the corresponding SiO₂ layer by depth (the direction of the arrow in FIG. 8A) when the first treatment and the second treatment are performed. FIG. 8A and FIG. 8B may be a result of performing FIG. 5.

As shown in FIG. 8A, the gap is filled with SiO₂ layer without forming a void therein. In FIG. 8B, the fluorine in the SiO₂ film is reduced to less than 2% and distributed evenly throughout the depth after the first treatment and the second treatment. Compared to FIG. 7B, FIG. 8B shows that the second inhibiting layer formed on the upper portion of the gap is significantly removed by the post treatment.

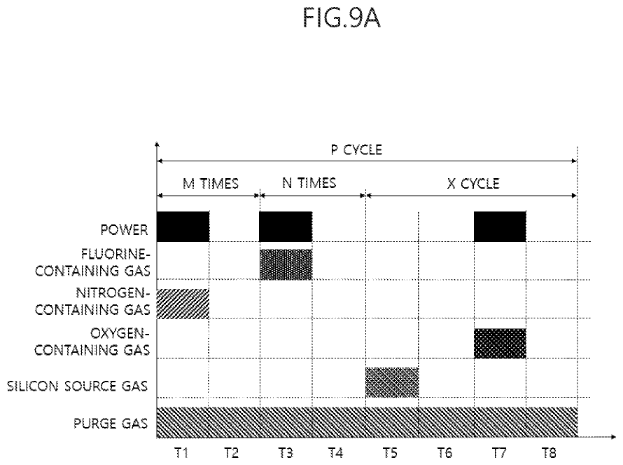

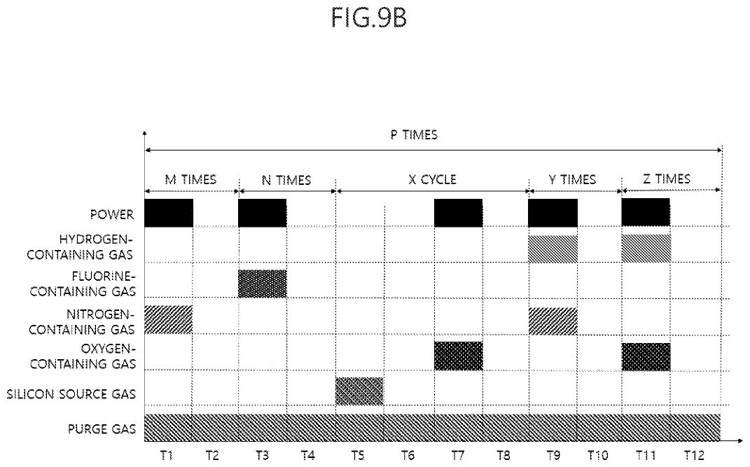

FIG. 9A illustrates a timing graph for the gap fill method according to an embodiment of the present disclosure. FIG. 9A may correspond to FIG. 2

In T1, the first inhibiting layer may be formed by supplying a nitrogen-containing gas as the first inhibitor while applying the first power, followed by T2, a purge step. The first power may be either a single frequency power or a dual frequency power. The purge step T2 may be supplied with a purge gas (e.g., Ar). The purge gas may be supplied from T1 through T8.

In T3, the second inhibiting layer may be formed by supplying a fluorine-containing gas as the second inhibitor while applying the second power, followed by T4, a purge step. The second power may be either a single frequency power or a dual frequency power.

In T5 to T8, a silicon-containing layer may be formed by PEALD method. The silicon-containing layer may be SiO₂ by supplying a silicon source gas in T5 and an oxygen-containing gas in T7 while applying the third power in T7.

In FIG. 9A, each of forming the first inhibiting layer (T1 to T2), forming the second inhibiting layer (T3 to T4) and forming the silicon-containing layer (T5 to T8) may be repeated at least one time (i.e., M, N and X≥1).

In another embodiment of FIG. 9A, the method may further comprise a super cycle repeating a plurality of times (i.e., P≥1) sub-steps comprising the first inhibiting layer (T1 to T2), forming the second inhibiting layer (T3 to T4) and forming the silicon-containing layer (T5 to T8).

FIG. 9B illustrates a timing graph for the gap-fill method according to an embodiment of the present disclosure. FIG. 9B may correspond to FIG. 5.

In T1, the first inhibiting layer may be formed by supplying a nitrogen-containing gas as the first inhibitor while applying the first power, followed by T2, a purge step. The first power may be either a single frequency power or a dual frequency power. The purge step T2 may be supplied with a purge gas (e.g., Ar). The purge gas may be supplied from T1 through T12.

In T3, the second inhibiting layer may be formed by supplying a fluorine-containing gas as the second inhibitor while applying the second power, followed by T4, a purge step. The second power may be either a single frequency power or a dual frequency power.

In T5 to T8, a silicon-containing layer may be formed by PEALD method. The silicon-containing layer may be SiO₂ by supplying a silicon source gas in T5 and an oxygen-containing gas in T7 while applying the third power in T7.

In T9 to T12, a post treatment may be performed to the silicon-containing layer. Specifically, the post treatment may comprise the first treatment from T9 to T10 and the second treatment from T11 to T12.

In T9, the first treatment may be performed by supplying the first treatment gas while applying the fourth power, followed by T10, a purge step. The first treatment gas may comprise at least one of a nitrogen-containing gas and a hydrogen-containing gas to remove the residual fluorine-containing gas from the silicon-containing layer. The residual fluorine-containing gas in the layer may react with the first treatment gas and be removed as gaseous byproducts (e.g., NF₃, HF, etc.). The fourth power may be either a single frequency power or a dual frequency power.

In T11, the second treatment may be performed by supplying the second treatment gas while applying the fifth power, followed by T12, a purge step. The second treatment gas may comprise at least one of an oxygen-containing gas and a hydrogen-containing gas to remove the residual nitrogen from the silicon-containing layer. The residual nitrogen-containing gas in the layer may react with the second treatment gas and be removed as gaseous byproducts (e.g., NO₂, H₂O, etc.). The fourth power may be either a single frequency power or a dual frequency power.

On the other hand, after the residual fluorine-containing gas is removed from the silicon-containing layer, the sites which the fluorine occupied originally may remain as vacancies. Therefore, the oxygen supplied in T11 may provide an extra oxygen to the vacancies, resulting in recovering the stoichiometry of the silicon-containing oxide layer (e.g., SiO₂).

In FIG. 9B, each of forming the first inhibiting layer (T1 to T2), forming the second inhibiting layer (T3 to T4), forming the silicon-containing layer (T5 to T8), performing the first treatment (T9 to T10) and performing the second treatment (T11 to T12) may be repeated at least one time (i.e., M, N, X, Y and Z≥1).

In another embodiment of FIG. 9B, the method may further comprise a super cycle repeating a plurality of times (i.e., P≥1) sub-steps comprising the first inhibiting layer (T1 to T2), forming the second inhibiting layer (T3 to T4), forming the silicon-containing layer (T5 to T8), performing the first treatment (T9 to T10) and performing the second treatment (T11 to T12).

Table 1 shows process conditions for SiO₂ gap fill according to an embodiment of the present disclosure.

TABLE 1
Process conditions for SiO₂ gap fill

| | | First | Second | | First | Second |
|---|---|---|---|---|---|---|
| | | inhibiting | inhibiting | Deposition | treatment | treatment |
| | | step | step | step | step | step |
| Gas flow | Si source | | | 100 to | | |
| condition | carrier Ar | | | 500 | | |
| (sccm) | Purge Ar | 500 to | 2,000 to | 500 to | 500 to | 500 to |
| | | 1,500 | 5,000 | 1,500 | 1,500 | 1,500 |
| | O₂ | | | 500 to | | 500 to |
| | | | | 1,500 | | 1,500 |
| | N₂ | 1,000 to | | | 1,000 to | |
| | | 3,000 | | | 3,000 | |
| | NF₃ | | 1,000 to | | | |
| | | | 10,000 | | | |
| Plasma | Frequency | 10 to | 10 to | 10 to | 10 to | 10 to |
| condition | (MHz) | 30 | 30 | 30 | 30 | 30 |
| | Power | 50 to | 15 to | 100 to | 300 to | 100 to |
| | (W) | 2,0000 | 500 | 300 | 600 | 300 |
| Step time | Si source | | | 0.1 to | | |
| (second) | feeding | | | 0.5 | | |
| | Purge | | | 0.1 to | | |
| | | | | 0.5 | | |
| | Plasma-on | 6 to | 0.1 to | 0.1 to | 10 to | 0.5 to |
| | | 50 | 5 | 0.5 | 150 | 2.0 |
| | Purge | | | 0.03 to | | |
| | | | | 0.5 | | |

| | | | | | |
|---|---|---|---|---|---|
| Pressure (Pa) | 400 | 400 | 400 | 400 | 400 |
| Process temperature | 200 to | 200 to | 200 to | 200 to | 200 to |
| (° C.) | 400 | 400 | 400 | 400 | 400 |
| Si source | | | aminosilane | | |

What is claimed is:

1. A method of filling a gap of a substrate, comprising:
providing the substrate with the gap in a reactor;
forming a first inhibiting layer on the substrate by supplying a first inhibitor comprising a nitrogen-containing gas while applying a first power to the reactor;
forming a second inhibiting layer by supplying a second inhibitor comprising a fluorine-containing gas while applying a second power to the reactor, and removing the first inhibiting layer; and
forming a silicon-containing layer on the substrate,
wherein, the first inhibiting layer and the second inhibiting layer are formed on an upper portion of the gap, and the silicon-containing layer is formed on a lower portion of the gap.

2. The method of claim 1, wherein the silicon-containing layer is a silicon oxide formed by repeating a method comprising:
supplying a silicon source gas; and
supplying an oxygen-containing gas while applying a third power.

3. The method of claim 2, wherein the silicon source gas comprises at least one of trisilylamine ((SiH₃)₃N); disilane ((SiH₃)₂); disilylmethylamine ((SiH₃)₂NMe); disilylethylamine ((SiH₃)₂NEt); disilylisopropylamine ((SiH₃)₂N(iPr)); disilyl-tert-butylamine ((SiH₃)₂N(tBu)); diethylsilylamine (SiH₃NEt₂); di-tert-butylsilylamine (SiH₃N(tBu)₂); bis-diethylamino-silane (SiH₂(NEt₂)₂); bis-dimethylamino-silane (SiH₂(NMe₂)₂); bis-tertiarybutylamino-silane(SiH₂(NHtBu)₂); diisopropylaminosilane(SiH₃N(iPr)₂); tetraethylorthosilicate (Si(OEt)₄); 1,2-bis(triethoxysilyl)ethane ([CH₂Si(OC₂H₅)₃]₂); Bis(triethoxysilyl)methane (CH₂[Si(OC₂H₅)₃]₂); bis(methyldiethoxysilyl)ethane ([CH₂Si(OC₂H₅)₂(OCH₃)]₂); bis(methyldiethoxysilyl)methane (CH₂[Si(OC₂H₅)₂(OCH₃)]₂); Aminopropyltrimethoxysilane (NH₂C₃H₆)Si(OCH₃)₃; silicon tetrachloride (SiCl₄); hexachlorodisilane (Si₂Cl₆); tris-dimethylamino-silane (SiH(N(Me)₂)₃); bis-ethylmethylamino-silane (SiH₂[N(Et)(Me)]₂); hexakis-ethylamino-disilane (Si₂(NHEt)₆); tetrakis-ethylamino-silane (Si(NHEt)₄); or trisilane (Si₃H₈) or a mixture thereof.

4. The method of claim 2, wherein the oxygen-containing gas comprises at least one of O₂, O₃, or H₂O, or a mixture thereof.

5. The method of claim 2, wherein the third power is applied with a power of between about 100 W and about 300 W at a frequency between about 10 MHz and about 30 MHz.

6. The method of claim 1, wherein the first inhibitor comprises at least one of N₂, NH₃, NH₄, N₂H₂, or N₂H₄ or a mixture thereof.

7. The method of claim 1, wherein the second inhibitor comprises at least one of F₂, SF₆, CF₄, C₂F₆, CHF₃, CH₂F₂, ClF₃, NF₃, C₃F₈, C₄F₈, HF, or SiF₄ or a mixture thereof.

8. The method of claim 1, wherein the first power is applied with a power of between about 50 W and about 2,000 W at a frequency of between about 10 MHz and about 30 MHz.

9. The method of claim 8, wherein the first power is applied with an additional power of between about 50 W and about 500 W at a frequency of between about 300 kHz and about 1 MHz.

10. The method of claim 1, wherein the second power is applied with a power of between about 15 W and about 500 W at a frequency of between about 10 MHz and about 30 MHz.

11. The method of claim 10, wherein the second power is applied with an additional power of between about 15 W and about 500 W at a frequency of between about 300 kHz and about 11 MHz.

12. The method of claim 1, wherein each of forming the first inhibiting layer, forming the second inhibiting layer and forming the silicon-containing layer is repeated at least one time.

13. The method of claim 12, wherein the method further comprises a super cycle repeating sub-steps comprising the method of claim 12 a plurality of times.

14. The method of claim 1, wherein the method further comprises performing a post treatment to the silicon-containing layer.

15. The method of claim 14, wherein performing the post treatment comprises,
a first treatment by supplying a first treatment gas comprising at least one of a nitrogen-containing gas and a hydrogen-containing gas to remove the residual fluorine-containing gas from the silicon-containing layer while applying a fourth power; and
a second treatment by supplying a second treatment gas comprising at least one of an oxygen-containing gas and a hydrogen-containing gas to remove the residual nitrogen-containing gas from the silicon-containing layer while applying a fifth power.

16. The method of claim 15, wherein the fluorine in the silicon-containing layer is less than 2%.

17. The method of claim 15, wherein the first treatment gas comprises at least one of N₂, NH₃, NH₄, N₂H₂, N₂H₄, or H₂ or a mixture thereof.

18. The method of claim 15, wherein the second treatment gas comprises at least one of O₂, O₃, H₂O₂, H₂O, or H₂ or a mixture thereof.

19. The method of claim 14, wherein each of the fourth power and the fifth power is applied with a power of between about 50 W and about 2,000 W at a frequency of between about 10 MHz and about 30 MHz.

20. The method of claim 19, wherein each of the fourth power and the fifth power is applied with an additional power of between about 15 W and about 500 W at a frequency of between 300 kHz and about 1 MHz.

21. The method of claim 15, wherein each of forming the first inhibiting layer, forming the second inhibiting layer, forming the silicon-containing layer, performing the first treatment and performing the second treatment is repeated at least one time.

22. The method of claim 21, wherein the method further comprises a super cycle repeating sub-steps comprising the method of claim 21 a plurality of times.
